(19) United States
(12) Patent Application Publication
(10) Pub. No.: US 2008/0180010 A1
(43) Pub. Date: Jul. 31, 2008

(54) Electric box and cooling storage

(75) Inventors: Harunobu Iguchi, Ota-shi (JP); Satoshi Tsuji, Gunma-ken (JP); Junji Shirakusa, Okegawa-shi (JP)

Correspondence Address: KRATZ, QUINTOS & HANSON, LLP, 1420 K Street, N.W., Suite 400, WASHINGTON, DC, 20005, US

(73) Assignee: SANYO ELECTRIC CO., LTD., Moriguchi-shi (JP)

(21) Appl. No.: 12/010,448

(22) Filed: Jan. 25, 2008

(30) Foreign Application Priority Data
Jan. 31, 2007 (JP) 21003/2007

(51) Int. Cl. H01L 23/48; A47B 96/04

(52) U.S. Cl. 312/401; 174/551

(57) ABSTRACT

There is disclosed an electric box which can facilitate a connecting operation of electric-box-side coupler and lead-wire-side coupler while suppressing attachment of dust or the like to connecting portions between the couplers. In the electric box, electric components are stored in an outer case, the electric box is connected to external lead wires, the electric box includes the electric-box-side coupler detachably connected to the lead-wire-side coupler attached to distal end of the lead wire, and a coupler receiving portion constituted in the outer case, the electric-box-side coupler selectively has a received state in which the coupler is positioned in the coupler receiving portion and an exposed state in which the couplers are exposed from the coupler receiving portion, and the electric-box-side coupler and the lead-wire-side coupler connected to the electric-box-side coupler are detachably received in the coupler receiving portion in the received state.

### BACKGROUND OF THE INVENTION

The present invention relates to an electric box in which electric components are received in an outer case and which is connected to external lead wires, and it also relates to a cooling storage provided with the electric box.

Heretofore, in the cooling storage, a part of a main body has been constituted of a mechanical chamber in which a compressor and a condenser are installed, and this mechanical chamber has further been provided with an electric box in which a power supply substrate, a control circuit, switches, relays and the like are received.

For example, in a cooling storage disclosed in Japanese Patent Application Laid-Open No. 7-159025 (a patent document), a plurality of lead wires such as a power supply cord and unit wires are drawn from a rear surface of this electric box. Moreover, a main-body-side rail is attached to a top surface of the mechanical chamber so as to extend back and forth, and an electric-box-side rail is similarly attached to a top surface of the electric box so as to extend back and forth. Therefore, the electric-box-side rail is slidably held on the main-body-side rail provided on the top surface of the mechanical chamber, whereby the electric box is attached so as to be movable back and forth.

The electric box is hung on an upper part of the mechanical chamber from a time when the electric box is inserted to a state in which the box is fixed, and the lead wires drawn and hung from the electric box are received in the mechanical chamber without being nipped between the electric box and other components.

In the electric box disclosed in the above document, the electric box can be drawn to a front part of the mechanical chamber, and therefore even when the lead wires received in the mechanical chamber are drawn toward a distal end, the electric box is drawn toward the front part to easily connect electric-box-side couplers provided on an electric box side to lead-wire-side couplers attached to distal ends of the lead wires.

However, in this case, an operation of connecting the electric-box-side couplers to the lead-wire-side couplers is performed outside the electric box. Therefore, there is a disadvantage that dust, water droplets and the like are attached to connecting portions between these couplers, and hence these connecting portions are separately covered with vinyl bags or the like to suppress the attachment of the dust and the like. However, such covering with the vinyl bags causes ignition of a fire. Therefore, these connecting portions are covered especially using a metal box or the like to suppress the attachment of the dust and the like.

However, in such a constitution, the mechanical chamber having a limited space is further provided with the metal box for covering the connecting portions, thereby narrowing the inside of the mechanical chamber. Every time the couplers are connected, the metal box has to be opened and closed, an operation becomes laborious, and an operator might forget to connect the couplers.

### SUMMARY OF THE INVENTION

The present invention has been developed to solve a conventional technical problem, and an object thereof is to provide an electric box which can facilitate an operation of connecting electric-box-side coupler to lead-wire-side coupler while suppressing attachment of dust and the like to connecting portions between the couplers, and provide a cooling storage including the electric box.

An electric box of a first invention is an electric box in which electric components are stored in an outer case and which is connected to external lead wire, the electric box characterized by comprising: electric-box-side coupler detachably connected to lead-wire-side coupler attached to distal end of the lead wire; and a coupler receiving portion constituted in the outer case, the electric-box-side coupler selectively has a received state in which the coupler is positioned in the coupler receiving portion and an exposed state in which the coupler is exposed from the coupler receiving portion, and the electric-box-side coupler and the lead-wire-side coupler connected to the electric-box-side coupler are detachably received in the coupler receiving portion in the received state.

The electric box of a second invention is characterized in that the above invention includes a coupler attachment member which is drawably provided in the coupler receiving portion and to which the electric-box-side coupler is attached, the coupler attachment member is pushed into the coupler receiving portion to bring the electric-box-side coupler into the received state, and a part of the coupler attachment member is exposed from the coupler receiving portion in the state.

The electric box of a third invention is characterized in that the above invention includes a holding structure to hold a state in which the coupler attachment member is pushed into the coupler receiving portion and a state in which the coupler attachment member is drawn from the coupler receiving portion.

A cooling storage of a fourth invention is characterized by comprising: an insulation box body in which a storage chamber is constituted; and a cooling unit detachably brought into close contact with the insulation box body, the cooling unit includes an electric box connected to lead wire from a device constituting the cooling unit, the electric box has an outer case in which electric components are stored, electric-box-side coupler detachably connected to lead-wire-side coupler attached to distal end of the lead wire, and a coupler receiving portion constituted in the outer case, the electric-box-side coupler is provided detachably from a received state in which the coupler is positioned in the coupler receiving portion to an exposed state in which the couplers is exposed from the coupler receiving portion, in the received state, the electric-box-side coupler and the lead-wire-side coupler connected to the electric-box-side coupler are detachably received in the coupler receiving portion, the cooling unit is detached from the insulation box body to bring the electric-box-side coupler into the exposed state, and the electric-box-side coupler shift to the received state in conjunction with an operation of providing the cooling unit so as to come in close contact with the insulation box body.

The cooling storage of a fifth invention is characterized in that the above invention includes a coupler attachment member which is movably provided on the coupler receiving portion and to which the electric-box-side coupler is attached; and an operation member which is connected to the coupler attachment member to protrude from the outer case, and when the cooling unit is provided so as to come in close contact with the insulation box body, the operation member abuts on the insulation box body to move the coupler attachment member and bring the electric-box-side couplers into the received state.

According to the first invention, in the electric box, the electric components are stored in the outer case, the electric box is connected to the external lead wire, and the electric box includes the electric-box-side coupler detachably connected to the lead-wire-side coupler attached to the distal end of the lead wire, and the coupler receiving portion constituted in the outer case, the electric-box-side coupler selectively has the received state in which the coupler is positioned in the coupler receiving portion and the exposed state in which the coupler is exposed from the coupler receiving portion, and the electric-box-side coupler and the lead-wire-side coupler connected to the electric-box-side coupler are detachably received in the coupler receiving portion in the received state. Therefore, in the exposed state, the electric-box-side coupler can easily be connected to the lead-wire-side coupler, and in the received state, these electric-box-side coupler and lead-wire-side coupler can be protected from water immersion from the outside, attachment of dust and the like.

In consequence, the water immersion and the attachment of the dust which are causes for a fire can effectively be suppressed. Moreover, even if these connecting portions catch fire, the portions are received in the electric box, and hence it can effectively be prevented that other portions catch fire.

According to the second invention, in addition to the above invention, the electric box includes the coupler attachment member which is drawably provided in the coupler receiving portion and to which the electric-box-side coupler is attached, the coupler attachment member is pushed into the coupler receiving portion to bring the electric-box-side coupler into the received state, and a part of the coupler attachment member is exposed from the coupler receiving portion in the state. In consequence, the coupler attachment member can be operated to easily bring the electric-box-side coupler into the received state and the exposed state.

In particular, a part of the coupler attachment member is exposed from the coupler receiving portion, so that the exposed portion of the member can be picked and drawn to easily expose the electric-box-side coupler from the coupler receiving portion. In consequence, an operation property improves, and a connecting operation can be simplified.

According to the third invention, in addition to the above inventions, the electric box includes the holding structure to hold the state in which the coupler attachment member is pushed into the coupler receiving portion and the state in which the coupler attachment member is drawn from the coupler receiving portion. In consequence, in the state in which the coupler attachment member is drawn, the electric-box-side coupler can easily be connected to the lead-wire-side coupler. Moreover, in the state in which the coupler attachment member is pushed into the coupler receiving portion, it is possible to avoid a disadvantage that the coupler attachment member easily jumps out of the coupler receiving portion owing to vibration or the like.

According to the fourth invention, in the cooling storage including the insulation box body in which the storage chamber is constituted, and a cooling unit detachably brought into close contact with the insulation box body, the cooling unit includes the electric box connected to the lead wire from the device constituting the cooling unit, the electric box has the outer case in which the electric components are stored, the electric-box-side coupler detachably connected to the lead-wire-side coupler attached to the distal ends of the lead wire, and the coupler receiving portion constituted in the outer case, the electric-box-side coupler is provided detachably from the received state in which the couplers is positioned in the coupler receiving portion to the exposed state in which the coupler is exposed from the coupler receiving portion, and in the received state, the electric-box-side coupler and the lead-wire-side coupler connected to the electric-box-side coupler are detachably received in the coupler receiving portion. In consequence, in the exposed state, the electric-box-side coupler can easily be connected to the lead-wire-side coupler, and in the received state, these electric-box-side coupler and lead-wire-side coupler can be protected from the water immersion from the outside, the attachment of the dust and the like.

In consequence, the water immersion and the attachment of the dust which are causes for the fire can effectively be suppressed. Moreover, even if these connecting portions catch fire, the portions are received in the electric box, and hence it can effectively be prevented that other portions catch fire.

In particular, according to the present invention, the cooling unit is detached from the insulation box body to bring the electric-box-side coupler into the exposed state, and the electric-box-side coupler can be moved to the received state in conjunction with the operation of providing the cooling unit so as to come in close contact with the insulation box body. In consequence, the electric-box-side coupler can be moved to the received state in conjunction with an operation of attaching the cooling unit to the insulation box body, and an assembly operation property can be improved.

Moreover, according to the fifth invention, in addition to the above inventions, the cooling storage includes the coupler attachment member which is movably provided on the coupler receiving portion and to which the electric-box-side coupler is attached, and the operation member which is connected to the coupler attachment member to protrude from the outer case, and when the cooling unit is provided so as to come in close contact with the insulation box body, the operation member abuts on the insulation box body to move the coupler attachment member and bring the electric-box-side coupler into the received state. In consequence, the operation member connected to the coupler attachment member abuts on the insulation box body to exert an operation force, and can move the coupler attachment member in such a direction as to bring the electric-box-side coupler into the received state.

In consequence, in a simple structure, the electric-box-side coupler can be brought into the received state in conjunction with the attachment of the cooling unit to the insulation box body.

### BRIEF DESCRIPTION OF THE DRAWINGS

FIG. 1 is a perspective view of a cooling storage to which the present invention is applied (Embodiment 1);

FIG. 2 is a vertical side view of the cooling storage;

FIG. 3 is a perspective view of a cooling unit;

FIG. 4 is a side view of the cooling unit;

FIG. 5 is a perspective view of a lift mechanism;

FIG. 6 is an exploded perspective view of an electric box;

FIG. 7 is a partially enlarged sectional view (a state in which a coupler attachment member is received in a coupler receiving portion) of the electric box;

FIG. 8 is a partially enlarged sectional view (a state in which the coupler attachment member is exposed from the coupler receiving portion) of the electric box;

FIG. 9 is a partially enlarged sectional view (a state in which a coupler attachment member is received in a coupler receiving portion) of an electric box (Embodiment 2);

FIG. 10 is a partially enlarged sectional view (a state in which the coupler attachment member is exposed from the coupler receiving portion) of the electric box (Embodiment 2);

FIG. 11 is a partially enlarged sectional view (a state in which a coupler attachment member is received in a coupler receiving portion) of an electric box (Embodiment 3);

FIG. 12 is a partially enlarged sectional view (a state in which the coupler attachment member is exposed from the coupler receiving portion) of the electric box (Embodiment 3);

FIG. 13 is an exploded perspective view of an electric box (Embodiment 4);

FIG. 14 is a partially enlarged sectional view (a state in which a coupler attachment member is received in a coupler receiving portion) of the electric box (Embodiment 4);

FIG. 15 is a partially enlarged sectional view (a state in which the coupler attachment member is exposed from the coupler receiving portion) of the electric box (Embodiment 4); and

FIG. 16 is an exploded perspective view of an electric box (Embodiment 5).

### DETAILED DESCRIPTION OF THE PREFERRED EMBODIMENTS

A cooling storage 1 to which an electric box 39 is applied according to the present invention will hereinafter be described in detail with reference to the drawings in accordance with Embodiments 1 to 5. It is to be noted that a constitution of the cooling storage 1 according to Embodiment 2 and the subsequent embodiments is substantially the same as that of the cooling storage 1 described in detail in Embodiment 1, the description thereof is therefore omitted, and constitutions of electric boxes of the embodiments will be described in detail.

### Embodiment 1

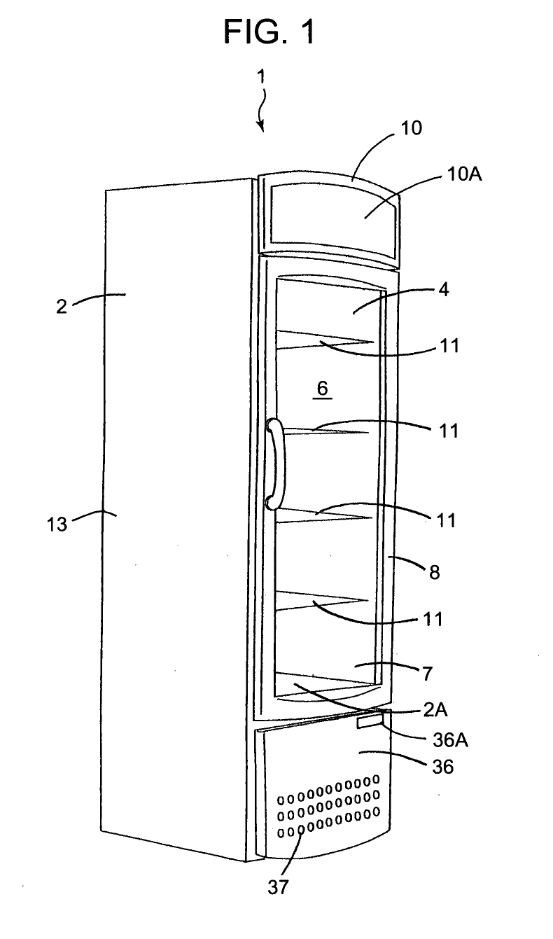

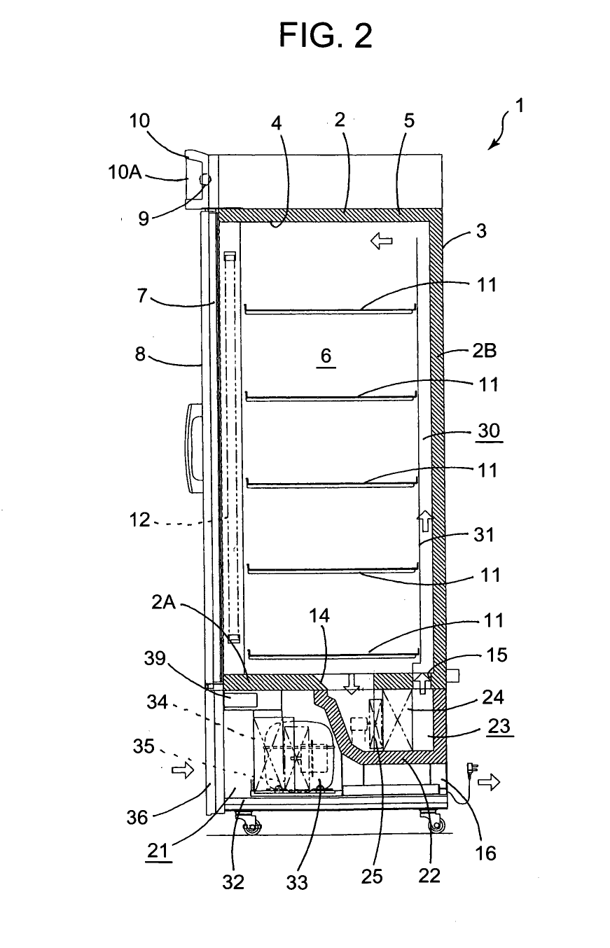

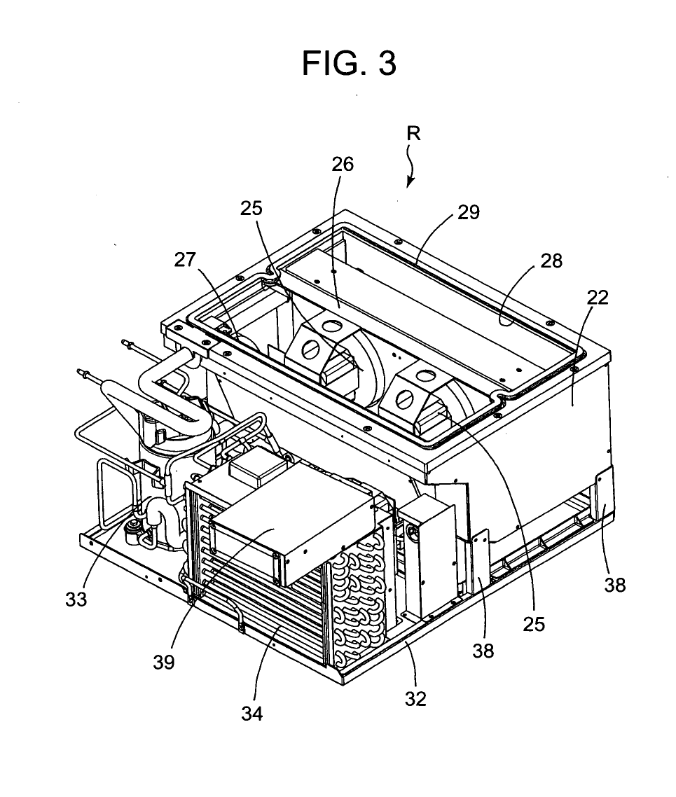

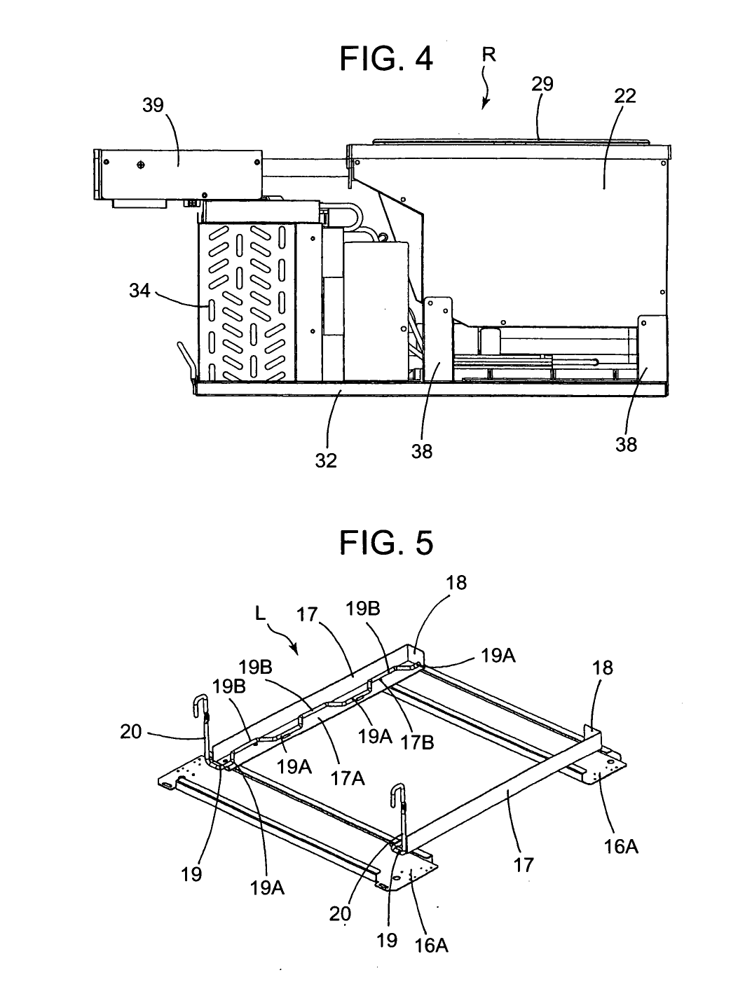

First, a cooling storage 1 provided with an electric box 39 according to Embodiment 1 will be described with reference to FIGS. 1 to 5. FIG. 1 is a perspective view of the cooling storage 1 to which the present invention is applied, FIG. 2 is a vertical side view of the cooling storage 1, FIG. 3 is a perspective view of a cooling unit, FIG. 4 is a side view of the cooling unit, and FIG. 5 is a perspective view of the cooling unit and a lift mechanism L.

In the cooling storage 1 of the present embodiment, a main body is constituted of a rectangular insulation box body 2 which opens in a front surface of the main body. This insulation box body 2 is constituted of an outer box 3 formed of a steel plate having an opening in a front surface of the insulation box body, an inner box 4 having an opening in the front surface, and an insulation material 5 foamed and introduced between the outer box 3 and the inner box 4. Moreover, in the insulation box body 2, a storage chamber 6 which opens in the front surface of the insulation box body is formed, and the front-surface opening of the storage chamber 6 is openably closed with a door 8 provided with glass 7 through which the inside of the storage chamber can be seen. The door 8 is a swing door having one side end which is rotatably supported on a side part of the insulation box body 2. Furthermore, in the storage chamber 6, a plurality of stages of shelves 11 . . . on which food and the like are to be mounted are extended. In addition, a fluorescent lamp 12 as illumination means for illuminating the inside of the storage chamber 6 and a front part of the storage chamber 6 is attached to a side surface of the insulation box body positioned on the front part of the storage chamber 6.

Moreover, a front-surface panel 10 is attached to a front part of a top surface of the insulation box body 2. A shade 10A constituted of a translucent material is attached to this front-surface panel 10, and a fluorescent lamp 9 as illumination means for illuminating a front part of the cooling storage 1 is attached to a rear part of this front-surface panel 10.

A base leg angle 16 having a predetermined height is attached to a bottom surface of the insulation box body 2, and opposite side surfaces of the base leg angle 16 together with opposite side surfaces of the insulation box body 2 are covered with a face panel 13. It is to be noted that a pair of fixing members 17, 17 described later in detail are attached to lower front and rear sides 16A, 16A of the base leg angle 16 constituting a bottom part of a mechanical chamber 21. The mechanical chamber 21 is formed under the insulation box body 2, and a cooling unit R of FIG. 3 is received. A cold air suction port 14 and a cold air discharge port 15 are formed through front and rear parts of a bottom wall 2A of the insulation box body 2 so as to extend through the insulation material 5.

A cooling box 22 having an opening in the upper surface thereof is provided so as to abut on a lower surface of the bottom wall 2A of the insulation box body 2 which is a ceiling of the mechanical chamber 21. A cooling chamber 23 is formed in this cooling box 22, and provided with a cooling unit 24 constituting a cooling device, and a blower 25 for the cooling unit is arranged before the cooling unit 24. It is to be noted that the upper-surface opening of this cooling box 22 is provided with a cold air suction port 27 and a cold air discharge port 28 on a cooling box 22 side by a partition plate 26 as shown in a perspective view of the cooling unit R of FIG. 3. The cold air suction port 27 and the cold air discharge port 28 correspond to the cold air suction port 14 and the cold air discharge port 15 formed in the bottom wall 2A of the insulation box body 2, respectively. Moreover, a seal material 29 (shown only in FIGS. 3 and 4) is attached to an opening edge of this cooling box 22 so as to come in close contact with and abut on the lower surface of the bottom wall 2A of the insulation box body 2.

On the other hand, a partition plate 31 is attached to an inner side of a back wall 2B of the insulation box body 2 to constitute a duct 30 which allows the cold air discharge port 15 formed through the bottom wall 2A to communicate with an upper part of the storage chamber 6. This partition plate 31 is provided with a plurality of openings (not shown) for supplying, into the storage chamber 6, cold air discharged from the blower 25 for the cooling unit. It is to be noted that this partition plate 31 may be provided with engagement portions which engage with the shelves 11.

On the other hand, in the mechanical chamber 21, an attachment base 32 constituting a bottom part of the cooling unit R is received, and this attachment base 32 is provided with a compressor 33, a condenser 34 and a blower 35 for the condenser which constitute the cooling device together with the cooling unit 24, the electric box 39 described later in detail and the like. An openable/closable panel 36 is attached to a front surface of the mechanical chamber 21 to cover the mechanical chamber 21. It is to be noted that this panel 36 is provided with a plurality of ventilation holes 37 which face a front part of the condenser 34, and a window 36A through which a display part attached to a front part of the electric box 39 arranged in the mechanical chamber 21 can be seen from the outside.

Here, a predetermined amount of carbon dioxide (CO₂) is introduced as a refrigerant in a refrigerant circuit of the cooling unit R. It is to be noted that the compressor 33 for use in the present embodiment is assumed to be a two-stage (multistage) compression type rotary compressor in which low stage side compression means (a first-stage rotary compression element), high stage side compression means (a second-stage rotary compression element) and a driving element for driving these compression means are received in a sealed container.

Moreover, the cooling box 22 is detachably held by cooling box support members 38 . . . which are provided at positions corresponding to four corners of a lower surface of the cooling box 22. In consequence, the cooling unit R constituted of the cooling box 22, the cooling unit 24, the blower 25 for the cooling unit, the compressor 33, the condenser 34 and the like is detachably received in the mechanical chamber 21 together with the attachment base 32, and the cooling unit can be separated from the insulation box body 2.

Furthermore, this mechanical chamber 21 is provided with the lift mechanism L which pushes up the cooling unit R together with the attachment base 32 toward the bottom wall 2A of the insulation box body 2. As shown in FIG. 5, this lift mechanism L is constituted of a pair of fixing members 17, 17 and a pair of lift members 19, 19. When the cooling unit R is received, the fixing members 17, 17 extend back and forth on opposite side parts of the cooling unit R, that is, from a proximal end of the mechanical chamber 21 to a distal end thereof, and the fixing members have a substantially L-shaped section which opens toward the inside of the mechanical chamber 21. A bottom surface 17A of each fixing member 17 is provided with a plurality of engagement holes 17B. The engagement holes 17B are superimposed on engagement holes (not shown) beforehand formed in the lower front and rear sides 16A of the base leg angle 16, and fixed with screws, whereby the fixing members 17 are fixed to the base leg angle 16. A side surface rear end of each fixing member 17 is provided with a stopper (positioning means) 18 bent substantially at right angles toward the inside of the mechanical chamber 21.

Each of the lift members 19 is formed of a steel rod having a circular section, and constituted so as to extend from a front end of the fixing member 17 to a rear end thereof, that is, from the proximal end of the mechanical chamber 21 to the distal end thereof. In the present embodiment, the steel rod is bent a plurality of times, 12 times in the present embodiment to constitute rotary shafts 19A including linear portions on a proximal end of the lift member, a distal end thereof and two portions between the proximal end and the distal end. The lift member 19 is also constituted of three top sides 19B formed by bending the steel rod so that portions between the rotary shafts 19A have a trapezoidal shape having an equal dimension (an equal height) in the same direction.

Moreover, the proximal end of this lift member 19 is provided with an arm portion 20 which is bent and formed integrally and continuously with the rotary shaft 19A positioned on the proximal end of the lift member. This arm portion 20 is bent substantially at 90 degrees from a front end of the rotary shaft 19A positioned on the proximal end, and bent outward on a side opposite to the mechanical chamber 21, and then an end of the arm portion is bent substantially vertically to a surface formed by the rotary shaft 19A and the top side 19B.

In consequence, in a state in which the rotary shafts 19A and the top sides 19B forming the lift member 19 come in contact with the bottom surface 17A of the fixing member 17, that is, in a state in which the top sides 19B fall on the bottom surface 17A of the fixing member 17, the arm portion 20 is raised substantially vertically to the bottom surface 17A of the fixing member 17. On the other hand, in a state in which the lift member 19 is rotated around the rotary shafts 19 to pull down the arm portion 20 toward the inside of the mechanical chamber 21, that is, in a substantially horizontal state, the top sides 19B of the lift member 19 are moved to a higher position as much as a predetermined height from the bottom surface 17A of the fixing member 17.

As described above, the attachment base 32 of the cooling unit R is received from a front part of the mechanical chamber 21. At this time, the attachment base 32 is positioned in a horizontal direction by side surfaces of both the fixing members 17, 17 fixed to the lower front and rear sides 16A, 16A of the base leg angle 16. Then, opposite ends of a lower surface of the attachment base 32 are allowed to abut on upper surfaces of the lift members 19 attached on inner sides of the fixing members 17, and the attachment base is slid toward the distal end until the attachment base abuts on the stoppers 18 formed on rear ends of the fixing members 17, thereby inserting the attachment base into the mechanical chamber 21.

Then, in a state in which the cold air suction port 27 and the cold air discharge port 28 of the cooling box 22 are disposed under the cold air suction port 14 and the cold air discharge port 15 of the bottom wall 2A of the insulation box body 2, an operation of pulling the arm portions 20 of the lift members 19 positioned on the opposite sides toward the inside of the mechanical chamber 21 is performed, whereby the lift members 19 formed integrally with the arm portions 20 are rotated around the rotary shafts 19A as described above.

In consequence, the top sides 19B of the lift members 19 brought into contact with the attachment base 32 are moved to push up the attachment base 32 as much as a dimension between the top side 19B and the rotary shaft 19A which are disposed apart from each other. Therefore, the cooling box 22 fixed to the attachment base 32 is also pushed upward, whereby the upper-surface opening of the cooling box 22 is allowed to abut on the lower surface of the bottom wall 2A of the insulation box body 2. Therefore, the cooling unit R in which the compressor 33, the condenser 34, the cooling box 22 and the like are integrated is attached to the bottom wall 2A of the insulation box body 2 without any trouble, and cold air circulation is constituted so that cold air which has performed heat exchange between the air and the cooling unit 24 is discharged into the storage chamber 6 from the cold air discharge port 15 by the blower 25 for the cooling unit, and sucked into the cooling chamber 23 from the cold air suction port 14, whereby the inside of the storage chamber 6 is cooled.

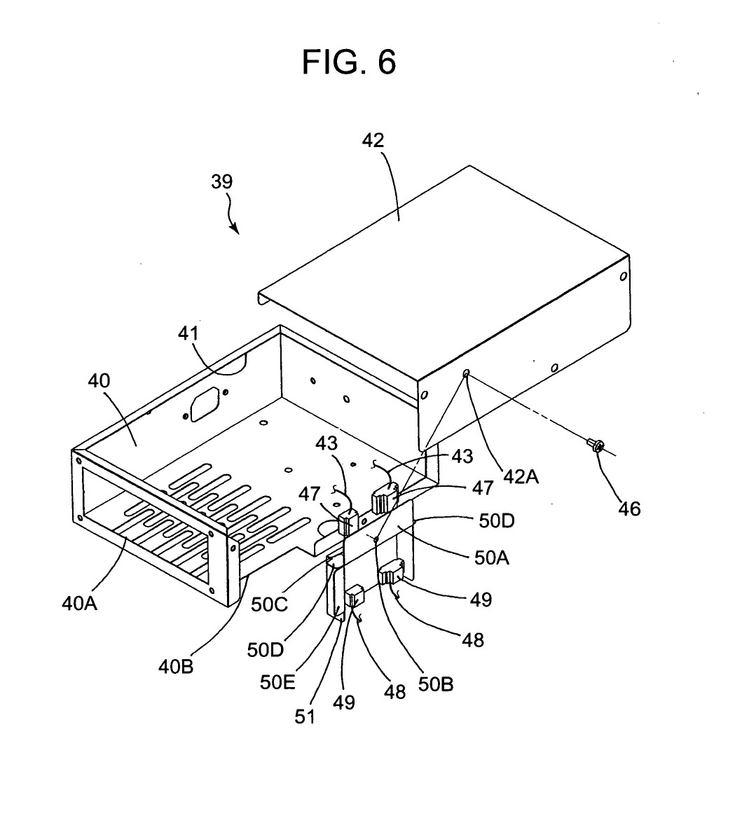

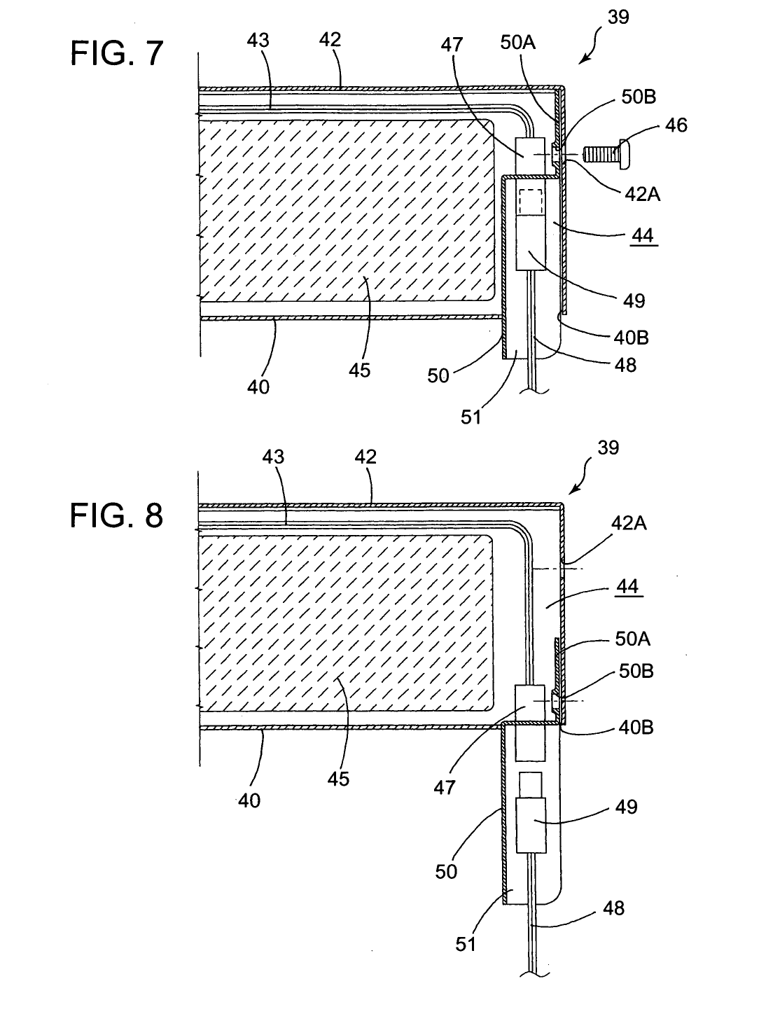

Next, a constitution of the electric box 39 according to the present invention will be described with reference to FIGS. 6 to 8. FIG. 6 shows an exploded perspective view of the electric box 39, FIG. 7 shows a partially enlarged sectional view (a state in which a coupler attachment member 50 is received in a coupler receiving portion 44) of the electric box 39, and FIG. 8 shows a partially enlarged sectional view (a state in which the coupler attachment member 50 is exposed from the coupler receiving portion 44) of the electric box 39.

The electric box 39 of the present embodiment is constituted of a rectangular body constituted of, for example, a metal material, and constituted of an outer case 40 having an opening 41 continued over an upper surface of the outer case and one side surface thereof as shown in FIG. 6, and a lid 42 similarly constituted of a metal material and formed into such a substantially L-shaped section as to openably close the opening 41.

In the outer case 40, an electric component 45 (shown only in FIGS. 7, 8) such as a substrate or a transformer is stored. The substrate is connected to a plurality of lead wires 43. Distal ends of the lead wires 43 in the outer case 40 in which the substrate is stored are connected to electric-box-side couplers 47, and lead-wire-side couplers 49 attached to distal ends of lead wires 48 connected to the outside, for example, the fluorescent lamps 9, 12 and the like in the present embodiment are detachably attached to the electric-box-side couplers 47.

A front surface of the outer case 40 is provided with a window 40A through which a display part stored in the outer case can be seen from the outside, and a transparent plate or the like is attached to the window 40A. It is to be noted that the window 40A corresponds to the window 36A formed in the panel 36 as described above, and the display part in the electric box 39 can be seen from the outside via these windows 36A, 40A.

Then, in one side part of this outer case 40, that is, a side part on an opening 41 side in the present embodiment, the coupler receiving portion 44 is formed so as to be positioned on an inner side of the outer case 40. In this coupler receiving portion 44, the coupler attachment member 50 is received, and can be inserted into and detached from an inlet/outlet 40B cut inward from a side end of a bottom surface corresponding to a projection surface of this coupler receiving portion 44.

This coupler attachment member 50 is used for connecting the electric-box-side couplers 47 to the lead-wire-side couplers 49. In the present embodiment, this coupler attachment member 50 is constituted of a rectangular body of a metal material, and continuously opens over a lower surface thereof and a side surface thereof positioned on a lid 42 side (a side surface of the outer case 40, in a case where the coupler receiving portion 44 is formed along the side surface of the outer case 40). Then, an upper surface of this coupler attachment member 50 is provided with an insertion hole 50C for attaching the electric-box-side couplers 47, and the electric-box-side couplers 47 are attached via the insertion hole 50C.

Then, an end of an upper surface of this coupler attachment member 50 is provided with movement regulation pieces (movement regulation means) 50D which extend outward, that is, the movement regulation piece which extends from a front end toward a front part and the further movement regulation piece which extends from a rear end toward a rear part, and the movement regulation pieces 50D are positioned above the bottom surface of the outer case 40.

Moreover, an upper edge of the opening of the side surface of this coupler attachment member 50 is provided with a slide surface 50A which extends upward substantially vertically, and a side edge thereof is provided with a slide surface 50E which extends outward substantially vertically. In the present embodiment, the slide surface 50A is provided with an engagement hole 50B. It is to be noted that this engagement hole 50B is superimposed on an engagement hole 42A formed in a side surface of the lid 42 and detachably attached via a screw 46 in a state in which the coupler attachment member 50 is received in the coupler receiving portion 44.

Furthermore, in this state in which this coupler attachment member 50 is received in the coupler receiving portion 44 of the electric box 39, as shown in FIG. 7, a lower end of the coupler attachment member is exposed from the electric box 39, that is, formed so as to extend downward from the bottom surface of the electric box 39, and this extended portion is an operation piece 51.

According to such a constitution, in the coupler attachment member 50, the operation piece 51 can be operated to select a received state (FIG. 7) in which the coupler attachment member is positioned in the coupler receiving portion 44 of the electric box 39 and an exposed state (FIG. 8) in which the coupler attachment member 50 is positioned under the electric box 39 and exposed from the coupler receiving portion 44.

Therefore, in a case where the cooling unit R is received in the mechanical chamber 21, an operation is performed to attach the electric-box-side couplers 47 of the electric box 39 provided on the attachment base 32 to the lead-wire-side couplers 49 of the distal ends of the lead wires 48 drawn from the main body of the cooling storage 1. In this case, first the operation piece 51 exposed from the coupler receiving portion 44 is operated to pull downward the coupler attachment member 50 received in the coupler receiving portion 44 of the electric box 39, while sliding the slide surfaces 50A, 50E along an inner surface of a side wall of the lid 42.

At this time, the upper surface of the coupler attachment member 50 is provided with the movement regulation piece 50D for preventing the end of the coupler attachment member 50 from being completely drawn from the coupler receiving portion 44. Therefore, the coupler attachment member 50 can be drawn from the coupler receiving portion 44 until the movement regulation pieces 50D abut on the bottom surface of the outer case 40.

In consequence, connecting portions of the electric-box-side couplers 47 provided in the coupler receiving portion 44 are exposed from the coupler receiving portion 44 together with the coupler attachment member 50 via the insertion hole 50C formed in the upper surface of the coupler attachment member 50.

In such an exposed state, the side surface of the coupler attachment member 50 is formed so as to open. Therefore, an operator can easily visually check the electric-box-side couplers 47 attached to the coupler attachment member 50, and can easily connect the lead-wire-side couplers 49 to the electric-box-side couplers 47.

After such a connecting operation of both the couplers 47, 49, the operator pushes the coupler attachment member 50 into the coupler receiving portion 44. In consequence, the electric-box-side couplers 47 and the lead-wire-side couplers 49 connected to the electric-box-side couplers are received in the coupler receiving portion 44. It is to be noted that in such a received state, the lead wires 48 connected to the lead-wire-side couplers 49 are drawn from the opening of the lower surface of the coupler attachment member 50.

Such a received state is set, whereby these electric-box-side couplers 47 and the lead-wire-side couplers 49 connected to the electric-box-side couplers can be protected from water immersion from the outside, especially from above, attachment of dust and the like. Therefore, the water immersion and the attachment of the dust which might cause a fire can effectively be suppressed. Moreover, even if the connecting portions between the couplers 47 and 49 catch fire, the couplers are received in the coupler receiving portion 44 of the electric box 39, and hence other portions can effectively be inhibited from catching fire.

As described above, the state in which the electric-box-side couplers 47 and the lead-wire-side couplers 49 connected to the electric-box-side couplers are received in the coupler receiving portion 44 and the state in which the couplers are exposed from the coupler receiving portion 44 can easily be switched. Therefore, simplification of the connecting operation of both the couplers and the protection of the connecting portions can effectively be realized.

Particularly in the present embodiment, the operation piece 51 constituting a part of the coupler attachment member 50 is exposed from the coupler receiving portion 44 in a state in which the coupler attachment member 50 is received in the coupler receiving portion 44. Therefore, the exposed operation piece 51 can be picked and drawn to easily expose the electric-box-side couplers 47 from the coupler receiving portion 44. In consequence, an operation property improves, and the connecting operation can be simplified.

Moreover, in the present embodiment, in the state in which the coupler attachment member 50 is received in the coupler receiving portion 44, the engagement hole 42A formed in the side surface of the lid 42 is superimposed on the engagement hole 50B formed in the slide surface 50A of the coupler attachment member 50, and then engaged via the screw 46 to fix the coupler attachment member 50 in the coupler receiving portion 44. In consequence, it is possible to avoid a disadvantage that the coupler attachment member 50 jumps downward owing to impact from the outside or the like and that the electric-box-side couplers 47 and that the lead-wire-side couplers 49 connected to the electric-box-side couplers are exposed from the coupler receiving portion 44.

Furthermore, in addition to the above embodiment, the coupler attachment member 50 may be provided with a holding structure to hold a state in which the coupler attachment member 50 is pushed into the coupler receiving portion 44 and a state in which the coupler attachment member is drawn outward. Embodiments provided with the holding structure will hereinafter be described in detail as Embodiments 2 and 3.

### Embodiment 2

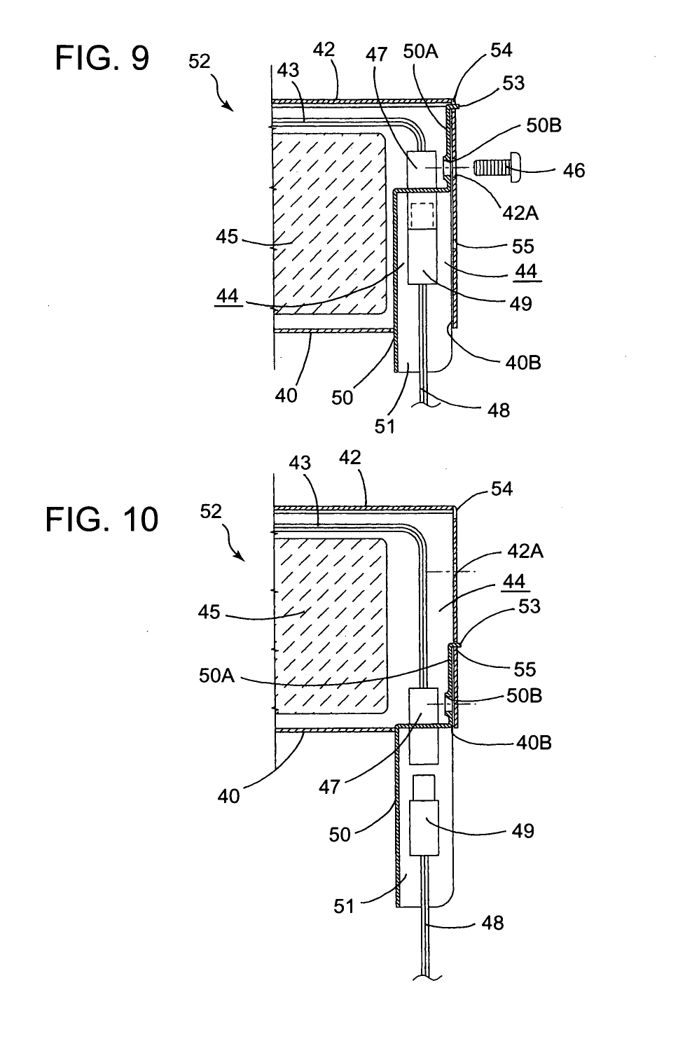

First, as Embodiment 2, an electric box 52 will be described in which a holding structure is constituted of a flange portion 53 and engagement holes 54, 55 for engaging the flange portion 53 with reference to partially enlarged sectional views of FIGS. 9 and 10. It is to be noted that in the drawings, components denoted with the same reference numerals as those of FIGS. 7 and 8 produce the same constitution and effect, and hence description thereof is omitted.

In such an embodiment, an upper end of a coupler attachment member 50, specifically, an upper end of a slide surface 50A is provided with the flange portion 53 which protrudes outward, that is, toward a lid 42 side. On the other hand, in a side surface of the lid 42 along which the slide surface 50A is slid, separately from the above-mentioned engagement hole 42A, the engagement holes 54, 55 are made at a position corresponding to the flange portion 53 in a case where the coupler attachment member 50 is received in a coupler receiving portion 44 and a position corresponding to the flange portion 53 in a state in which the coupler attachment member 50 is drawn and exposed from the coupler receiving portion 44, respectively.

According to such a constitution, as shown in FIG. 9, in the state in which the coupler attachment member 50 is received in the coupler receiving portion 44, the flange portion 53 enters the corresponding engagement hole 54 to prevent the coupler attachment member 50 from dropping down owing to a weight thereof. To bring the coupler attachment member 50 having such a state into an exposed state, once a lower end of the coupler attachment member 50 is inclined toward the side surface of the lid 42 to release engagement between the flange portion 53 and the engagement hole 54.

Afterward, the coupler attachment member 50 is drawn downward in the same manner as in the above embodiment to bring the coupler attachment member 50 into the exposed state from the coupler receiving portion 44 (FIG. 10). Even in such an exposed state, the flange portion 53 enters the engagement hole 55 formed at the corresponding position to prevent vertical movement of the coupler attachment member 50. In consequence, in a case where electric-box-side couplers 47 are connected to lead-wire-side couplers 49 in such a state, vertical movement of the electric-box-side couplers 47 is prevented by the engagement between the flange portion 53 and the engagement hole 55, so that a connecting operation of these couplers can be facilitated.

It is to be noted that after the connection of the couplers 47, 49, the lower end of the coupler attachment member 50 is again tilted toward the side surface of the lid 42 to release the engagement between the flange portion 53 and the engagement hole 55, and then the coupler attachment member is pushed into the coupler receiving portion 44 to bring the coupler attachment member 50 into the state in which the coupler attachment member is received in the coupler receiving portion 44. It is to be noted that even in such a case, the flange portion 53 enters the corresponding engagement hole 54 to prevent the coupler attachment member 50 from dropping down owing to a weight thereof in the same manner as described above. Therefore, even in a case where the coupler attachment member is not fixed via a screw 46, it is possible to avoid a disadvantage that the coupler attachment member 50 easily jumps out owing to vibration or the like.

### Embodiment 3

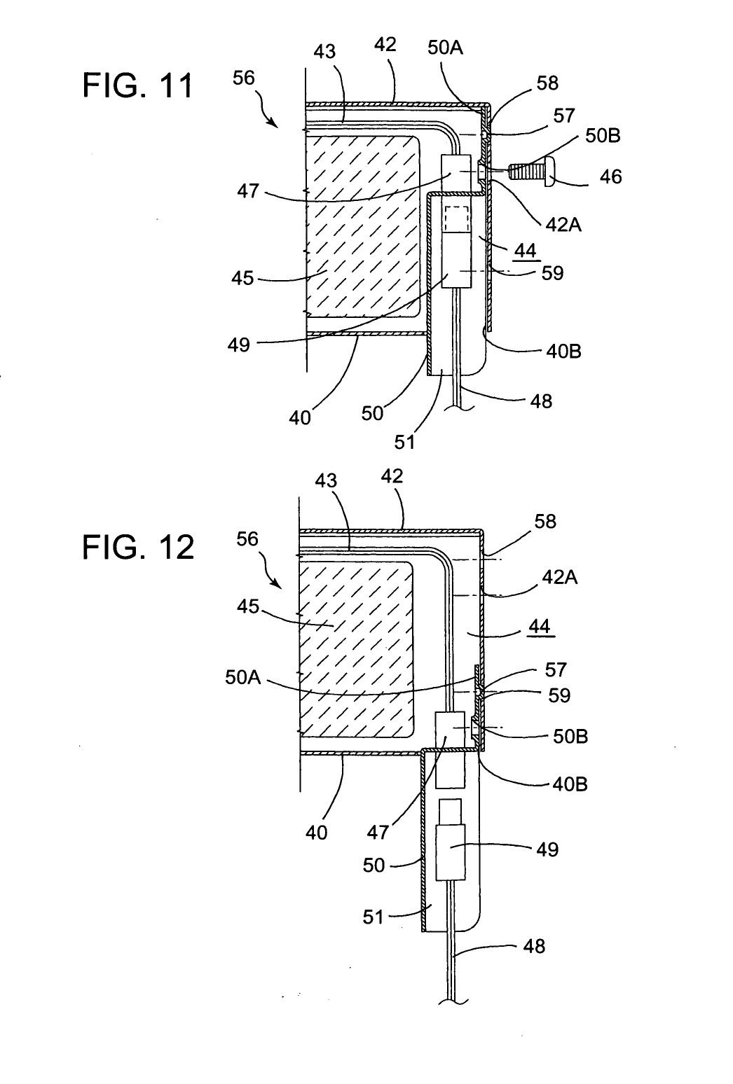

Next, as Embodiment 3, an electric box 56 will be described in which a holding structure is constituted of a protruding portion 57 and engagement holes 58, 59 for engaging the protruding portion 57 with reference to partially enlarged sectional views of FIGS. 11 and 12. It is to be noted that in the drawings, components denoted with the same reference numerals as those of FIGS. 7 and 8 produce the same constitution and effect, and hence description thereof is omitted.

In such an embodiment, an upper part of a coupler attachment member 50, specifically, a slide surface 50A is provided with the protruding portion 57 which protrudes outward, that is, toward a lid 42 side. On the other hand, in a side surface of the lid 42 along which the slide surface 50A is slid, separately from the above-mentioned engagement hole 42A, the engagement holes 58, 59 are made at a position corresponding to the protruding portion 57 in a case where the coupler attachment member 50 is received in a coupler receiving portion 44 and a position corresponding to the protruding portion 57 in a state in which the coupler attachment member 50 is drawn and exposed from the coupler receiving portion 44, respectively.

According to such a constitution, as shown in FIG. 11, in the state in which the coupler attachment member 50 is received in the coupler receiving portion 44, the protruding portion 57 enters the corresponding engagement hole 58 to prevent the coupler attachment member 50 from dropping down owing to a weight thereof. To bring the coupler attachment member 50 having such a state into an exposed state, a lower end of the coupler attachment member 50 is inclined toward the side surface of the lid 42 to release engagement between the protruding portion 57 and the engagement hole 58 in the same manner as in the above embodiment.

Afterward, the coupler attachment member 50 is drawn downward in the same manner as in the above embodiment to bring the coupler attachment member 50 into the exposed state from the coupler receiving portion 44 (FIG. 12). Even in such an exposed state, the protruding portion 57 enters the engagement hole 59 formed at the corresponding position to prevent vertical movement of the coupler attachment member 50. In consequence, in a case where electric-box-side couplers 47 are connected to lead-wire-side couplers 49 in such a state, vertical movement of the electric-box-side couplers 47 is prevented by the engagement between the protruding portion 57 and the engagement hole 59, so that a connecting operation of these couplers can be facilitated.

It is to be noted that after the connection of the couplers 47, 49, the lower end of the coupler attachment member 50 is again tilted toward the side surface of the lid 42 to release the engagement between the protruding portion 57 and the engagement hole 59, and then the coupler attachment member is pushed into the coupler receiving portion 44 to bring the coupler attachment member 50 into the state in which the coupler attachment member is received in the coupler receiving portion 44. It is to be noted that even in such a case, the protruding portion 57 enters the corresponding engagement hole 58 to prevent the coupler attachment member 50 from dropping down owing to a weight thereof in the same manner as described above. Therefore, even in a case where the coupler attachment member is not fixed via a screw 46, it is possible to avoid a disadvantage that the coupler attachment member 50 easily jumps out owing to vibration or the like.

### Embodiment 4

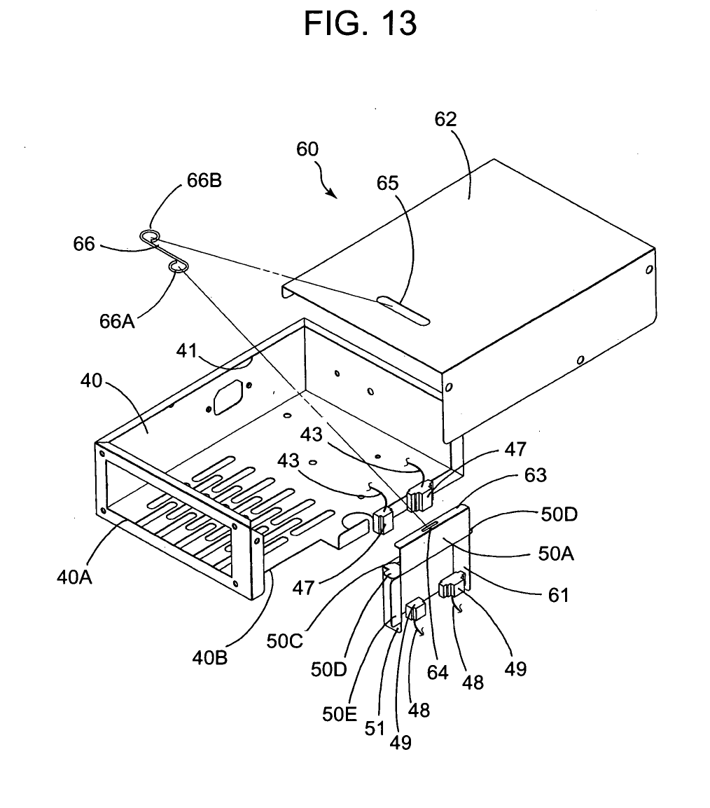

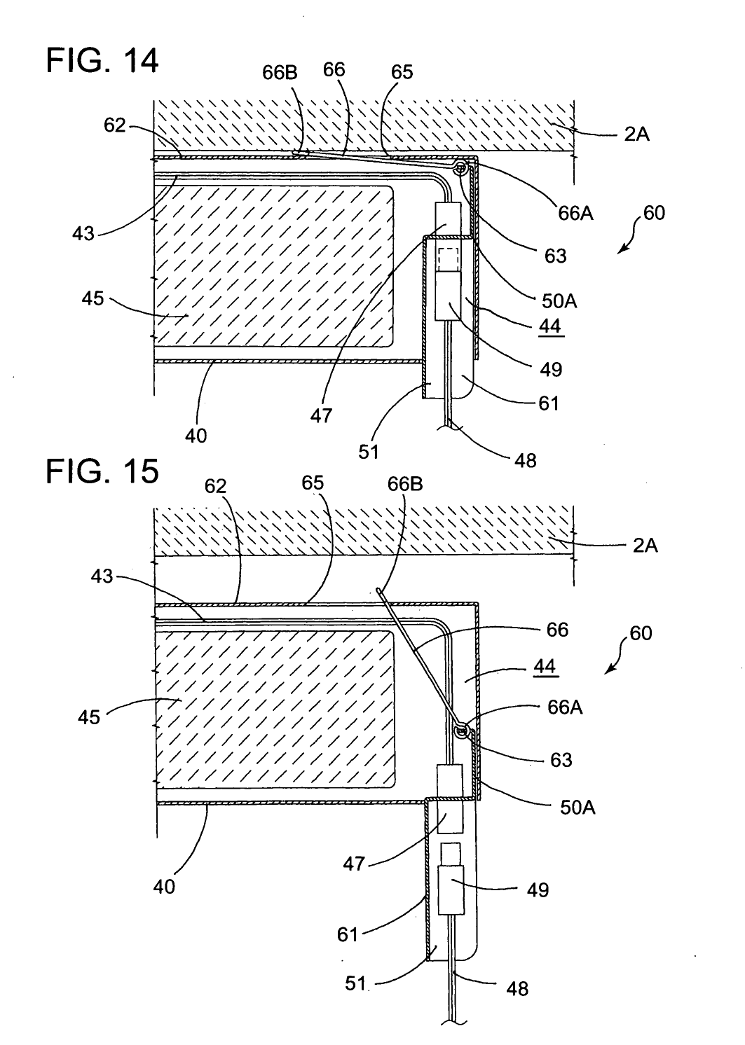

Next, a constitution of an electric box 60 as Embodiment 4 will be described with reference to FIGS. 13 to 15. FIG. 13 is an exploded perspective view of the electric box 60, FIG. 14 is a partially enlarged sectional view of the electric box 60, and FIG. 15 similarly shows a partially enlarged sectional view of the electric box 60. It is to be noted that in the drawings, components denoted with the same reference numerals as those of FIGS. 6 to 8 produce the same constitution and effect as those of the electric box 39 of Embodiment 1, and hence description thereof is omitted.

In the same manner as in the coupler attachment member 50 of Embodiment 1 described above, a coupler attachment member 61 provided on the electric box 60 according to such an embodiment is detachably received in a coupler receiving portion 44 from an inlet/outlet 40B provided in an outer case 40, and the coupler attachment member is continuously opened over a lower surface thereof and a side surface thereof (a side surface of the outer case 40, in a case where the coupler receiving portion 44 is formed along the side surface of the outer case 40) positioned on a lid 62 side. Moreover, electric-box-side couplers 47 are attached to this coupler attachment member 61 via an insertion hole 50C, and the coupler attachment member is provided with movement regulation pieces 50D and slide surfaces 50A, 50E.

Here, an upper end of the slide surface 50A is provided with a flange 63 bent inward, that is, toward the inside of the electric box 60, and the flange 63 is provided with an operation member attachment hole 64. Moreover, one end of an operation member 66 is attached to this operation member attachment hole 64.

On the other hand, a front portion of an upper surface of the lid 62 which covers openings of an upper surface and a side surface of the outer case 40 is provided with an operation member insertion hole 65, and this hole has an elongated hole shape which horizontally extends with respect to a front surface of the electric box 60. Moreover, at least the electric box 60 is attached to an attachment base 32 so that the upper surface of the lid 62 has a height substantially equal to or slightly smaller than that of an upper-surface opening of a cooling box 22.

In the present embodiment, the operation member 66 is constituted of a steel rod having a predetermined strength and having a circular section, and an end of the operation member is provided with engagement portions 66A, 66B forming planes crossing each other vertically. Therefore, as shown in FIG. 14, in a state in which the one engagement portion 66A is attached to the operation member attachment hole 64 of the coupler attachment member 61, the other engagement portion 66B is positioned above an electric component 45 in the outer case 40. Moreover, it is assumed that this operation member 66 is set so that the engagement portion 66B has such a length as to protrude upward as much as a predetermined dimension from the operation member insertion hole 65 of the lid 62 in a state in which the coupler attachment member 61 is drawn downward and exposed (FIG. 15) and so that the engagement portion 66B has such a length as to be positioned above an edge of the operation member insertion hole 65 on a side opposite to the coupler receiving portion 44 in a received state in which the coupler attachment member 61 is drawn into the coupler receiving portion 44 (FIG. 14).

According to such a constitution, the coupler attachment member 61 is brought into the exposed state (FIG. 15) from the coupler receiving portion 44 owing to a weight of the member itself in a state in which a cooling unit R is not lifted up toward a bottom wall 2A of an insulation box body 2 in a mechanical chamber 21. In such a state, it is possible to perform an operation of attaching the electric-box-side couplers 47 of the electric box 60 and lead-wire-side couplers 49 of distal ends of lead wires 48 drawn from a main body of a cooling storage 1 in the same manner as in the above embodiments.

Then, in a case where the cooling unit is lifted up toward the bottom wall 2A of the insulation box body 2 by the lift mechanism L, the engagement portion 66B of the operation member 66 protruding upward from the operation member insertion hole 65 of the lid 62 positioned at a height substantially equal to or slightly smaller than that of the upper-surface opening of the cooling box 22 abuts on the bottom wall 2A to exert an operation force, and the engagement portion 66B of the operation member 66 moves toward the side opposite to the coupler receiving portion 44 in the operation member insertion hole 65 of the lid 62 so as to avoid a pressing force exerted from below. In consequence, the operation member 66 substantially raised in the exposed state of the coupler attachment member 61 is turned down owing to such movement of the engagement portion, and the coupler attachment member 61 provided with the engagement portion 66A of the other end of the operation member 66 is pulled upward, that is, received in the coupler receiving portion 44.

In consequence, in conjunction with the cooling unit R brought into close contact with the bottom wall 2A of the insulation box body 2 in a simple structure, the coupler attachment member 61 can be pulled upward to bring the electric-box-side couplers 47 into the received state, and an assembly operation property can be improved.

On the other hand, in a case where maintenance or the like of the cooling unit R is performed, the lift mechanism L is operated to detach the cooling unit R from the insulation box body 2, whereby pressing of the engagement portion 66B of the operation member 66 by the insulation box body 2 from above is released, and the electric-box-side couplers 47 can be brought into the exposed state with the coupler attachment member 61 owing to the weights of the coupler attachment member 61 provided with the operation member 66 and the operation member 66 itself.

Therefore, unlike the above embodiments, the coupler attachment member does not have to be especially pulled down to bring the electric-box-side couplers 47 into the exposed state, or the coupler attachment member does not have to be pushed into the coupler receiving portion 44 to bring the electric-box-side couplers 47 into the received state, and the electric-box-side couplers 47 can be allowed to shift to each state in conjunction with the attachment operation of the cooling unit R to the insulation box body 2. It is possible to effectively realize simplification of a connecting operation of both the couplers 47, 49 and protection of the connecting portions.

Moreover, in the received state, these electric-box-side couplers 47 and the lead-wire-side couplers 49 connected to the electric-box-side couplers can be protected from water immersion from the outside, especially from above, attachment of dust and the like. Therefore, the water immersion and the attachment of the dust which might cause a fire can effectively be suppressed. Moreover, even if the connecting portions between the couplers 47 and 49 catch fire, the portions are received in the coupler receiving portion 44 of the electric box 60, and other portions can effectively be inhibited from catching fire.

Furthermore, in the present embodiment, in the state in which the coupler attachment member 61 is received in the coupler receiving portion 44, the operation member 66 is turned down by the lid 62 and the insulation box body 2 which comes close to the lid. Therefore, even if fixing members or the like are not especially used, it is possible to avoid a disadvantage that the coupler attachment member 61 jumps downward owing to impact from the outside or the like and that the electric-box-side couplers 47 and the lead-wire-side couplers 49 connected to the electric-box-side couplers are exposed from the coupler receiving portion 44.

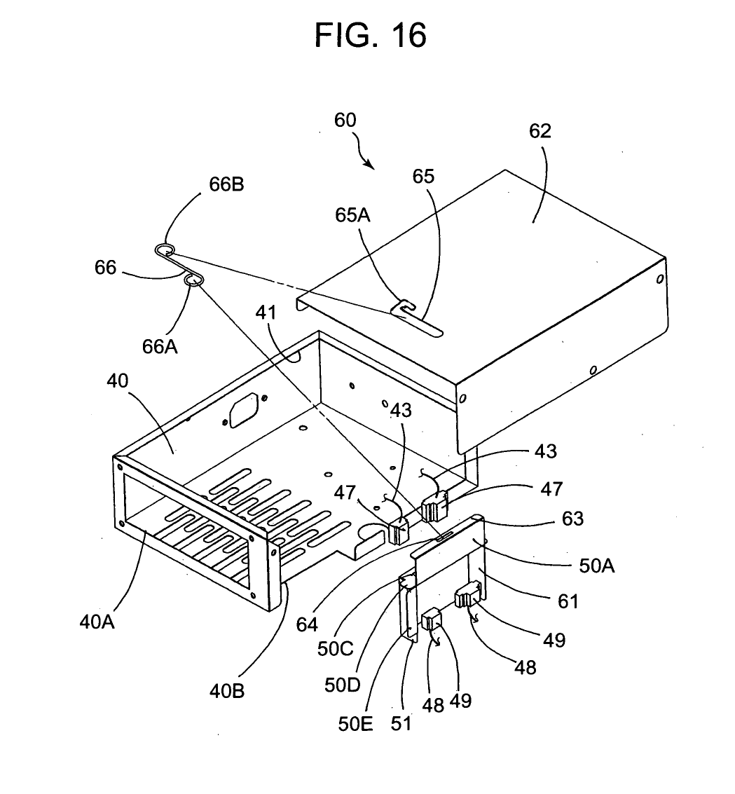

It is to be noted that in Embodiment 4 described above, the operation member 66 allows the coupler attachment member 61 to shift to the state in which the electric-box-side couplers 47 are exposed or the state in which the electric-box-side couplers are received in the coupler receiving portion 44. However, as in Embodiment 5 shown in FIG. 16, an operation member 66 protruding from an operation member insertion hole 65 may be picked, and moved in parallel toward a side opposite to a coupler receiving portion 44 in the operation member insertion hole 65 to arbitrarily move a coupler attachment member 61 to a state in which the coupler attachment member 61 exposes electric-box-side couplers 47 or a state in which the electric-box-side couplers are received in the coupler receiving portion 44 (vertically move the coupler attachment member 61).

In such a case, as shown in FIG. 16, an end of the operation member insertion hole 65 is provided with a substantially L-shaped engagement groove 65A having one end bent substantially in parallel with an insertion hole 65 side. Therefore, in the received state, an engagement portion 66B of the operation member 66 is engaged with the engagement groove 65A, whereby the received state may be maintained. Even in this case, it is possible to avoid a disadvantage that the coupler attachment member 61 jumps downward owing to impact from the outside or the like and that the electric-box-side couplers 47 and lead-wire-side couplers 49 connected to the electric-box-side couplers are exposed from the coupler receiving portion 44.

It is to be noted that in the above embodiments, the coupler attachment member 50 is vertically moved to insert the couplers into the coupler receiving portion 44 formed in the electric box and draw the couplers from the portion, but another method may be used. Examples of the method include a slide structure in which the coupler attachment member is moved in a lateral direction to insert the couplers into the coupler receiving portion 44 formed in the electric box and draw the couplers from the portion, and a method in which a coupler attachment member rotating around a rotary shaft is provided on a bottom surface of an outer case, and electric-box-side couplers are attached to an upper surface of the coupler attachment member to insert the couplers into the coupler receiving portion formed in the electric box and draw the couplers from the portion.

Moreover, in the above embodiments, the electric box is provided in the mechanical chamber formed under the insulation box body 2, but Embodiments 1, 2 and 3 may be modified so that the electric box is provided on the upper surface of the insulation box body 2 or the like, and the electric-box-side couplers attached to the coupler attachment member are moved in parallel to shift to a state in which the electric-box-side couplers are received in the coupler receiving portion 44 and a state in which the couplers are exposed from the coupler receiving portion 44.

What is claimed is:

1. An electric box in which electric components are stored in an outer case and which is connected to external lead wire, the electric box comprising:
electric-box-side coupler detachably connected to lead-wire-side coupler attached to distal end of the lead wire; and
a coupler receiving portion constituted in the outer case,
wherein the electric-box-side coupler selectively has a received state in which the coupler is positioned in the coupler receiving portion and an exposed state in which the coupler is exposed from the coupler receiving portion, and the electric-box-side coupler and the lead-wire-side coupler connected to the electric-box-side coupler are detachably received in the coupler receiving portion in the received state.

2. The electric box according to claim 1, further comprising: a coupler attachment member which is drawably provided in the coupler receiving portion and to which the electric-box-side coupler is attached, wherein the coupler attachment member is pushed into the coupler receiving portion to bring the electric-box-side coupler into the received state, and a part of the coupler attachment member is exposed from the coupler receiving portion in the state.

3. The electric box according to claim 2, further comprising: a holding structure to hold a state in which the coupler attachment member is pushed into the coupler receiving portion and a state in which the coupler attachment member is drawn from the coupler receiving portion.

4. A cooling storage comprising: an insulation box body in which a storage chamber is constituted; and a cooling unit detachably brought into close contact with the insulation box body,
wherein the cooling unit includes an electric box connected to lead wire from a device constituting the cooling unit,
the electric box has an outer case in which electric components are stored, electric-box-side coupler detachably connected to lead-wire-side coupler attached to distal end of the lead wire, and a coupler receiving portion constituted in the outer case,
the electric-box-side coupler is provided detachably from a received state in which the coupler is positioned in the coupler receiving portion to an exposed state in which the coupler is exposed from the coupler receiving portion, in the received state, the electric-box-side coupler and the lead-wire-side coupler connected to the electric-box-side couplers are detachably received in the coupler receiving portion,
the cooling unit is detached from the insulation box body to bring the electric-box-side coupler into the exposed state, and the electric-box-side coupler shift to the received state in conjunction with an operation of providing the cooling unit so as to come in close contact with the insulation box body.

5. The cooling storage according to claim 4, further comprising: a coupler attachment member which is movably provided on the coupler receiving portion and to which the electric-box-side coupler is attached; and an operation member which is connected to the coupler attachment member to protrude from the outer case,
wherein when the cooling unit is provided so as to come in close contact with the insulation box body, the operation member abuts on the insulation box body to move the coupler attachment member and bring the electric-box-side couplers into the received state.
